(19) United States
(12) Patent Application Publication
(10) Pub. No.: US 2012/0228011 A1
(43) Pub. Date: Sep. 13, 2012

(54) Semiconductor Load Board

(76) Inventors: Chien-Wei Chang, Taoyuan (TW); Ting-Hao Lin, Taipei (TW); Ya-Hsiang Chen, Yunlin (TW)

(21) Appl. No.: 13/043,462

(22) Filed: Mar. 9, 2011

(51) Int. Cl. H05K 1/09; H05K 1/00

(52) U.S. Cl. 174/257; 174/258

(57) ABSTRACT

Disclosed is a semiconductor load board, including a substrate, a plurality of connection pads, a patterned circuit layer, a dielectric layer, a plurality of solder pads, and a plurality of solders. The connection pads and the patterned circuit layer are located on the substrate. The dielectric layer is formed on the substrate, the connection pads and the patterned circuit layer, and has a plurality of openings corresponding to the plurality of connection pads. The solder pads are formed in the openings, and the width of the solder pads is smaller than or equals to the maximum width of the openings of the dielectric layer, and a protruding portion which has a width smaller than the minimum width of the openings of the dielectric layer can also be formed, such that the problems of short-circuit failure and electrical interference can be reduced.

### BACKGROUND OF THE INVENTION

1. Field of the Invention

The present invention relates to a semiconductor load board, and more particularly, to a semiconductor load board on which the width of the solder pads formed is smaller than or equal to the width of the opening of the dielectric layer formed.

2. The Prior Arts

FIG. 1 illustrates a cross sectional view of the semiconductor load board in prior arts. As shown in FIG. 1, the semiconductor load board 1 comprises a substrate 10, a plurality of connection pads 22, a patterned circuit layer 24, a dielectric layer 30, a plurality of solder pads 48, and a plurality of solders 58. The substrate 10 is made of polymer materials or ceramic materials, and the polymer materials comprise Bismaleimide Triazine (BT). The connection pads 22 and the patterned circuit layer 24 are located on the substrate 10, and are formed using a first conductive material comprising copper. The dielectric layer 30 is formed on the connection pads 22 and the patterned circuit layer 24, and has a plurality of openings 35 corresponding to the plurality of connection pads 22, wherein the openings 35 have a width reduced gradually toward the connection pads 22, and the minimum width is D1, and the maximum width is D2. The solder pads 48 are formed in the openings 35 corresponding to the connection pads 22 to fill up the openings 35. The solder pads 48 have a height higher than the height of the dielectric layer 30, and the width D6 of a portion higher than the dielectric layer 30 is wider than the maximum width D2 of the openings 35. The solder pads 48 are formed by a second conductive material which is copper or copper with nickel-gold or tin coating. The solders 58 are formed on the each solder pad 48 respectively to cover the solder pad 48 for connecting to external circuits (not shown).

While the technology develops, the number of the chips loaded on the same semiconductor load board increases. The structure of the prior arts has a problem that the solder pads are too closed to each other, and makes short-circuit failure and electrical interference more likely to occur. Therefore, a load board structure that can reduce the problems of the short-circuit failure and electrical interference is needed.

### SUMMARY OF THE INVENTION

A primary objective of the present invention is to provide a semiconductor load board comprising a substrate, a plurality of connection pads, a patterned circuit layer, a dielectric layer, a plurality of solder pads, and a plurality of solders. The connection pads and the patterned circuit layer are located on the substrate, and are formed by a first conductive material. The dielectric layer is then formed on top of the substrate, the connection pads and the patterned circuit layer, and has a plurality of openings corresponding to the plurality of connection pads, wherein the openings have a width reduced gradually toward the connection pads. The solder pads are formed in the openings corresponding to the connection pads to fill up the openings. The solder pads have a height higher than the height of the dielectric layer, and the width of a portion higher than the dielectric layer equals to the maximum width of the openings. The solder pads are formed by a second conductive material. The solders are formed on the each solder pad respectively to cover the solder pad for connecting to external circuits.

Another objective of the present invention is to provide a semiconductor load board, which is only variable in the width of solder pads and solders, and the other function and technical characteristics are not described again. The solder pads are formed in the openings corresponding to the connection pads to fill up the openings. The solder pads have a protruding portion which extends above the surface of the dielectric layer, and the width of the protruding portion is smaller than the maximum width of the openings. The solders are formed on the each solder pad respectively to cover the solder pad for connecting to external circuits.

Also another objective of the present invention is to provide a semiconductor load board, which is only variable in the width of the solder pads and solders, and the other function and technical characteristics are not described again. The solder pads are formed in the openings, and have a height higher than the height of the dielectric layer, and the width of the solder pads is smaller than the minimum width of the openings. The solders are formed on the each solder pad respectively to cover the solder pad for connecting to external circuits, and are partially formed in the openings and connected to the connection pads.

According to the semiconductor load board of the present invention, the wider intervals between solder pads are provides, such that the problems of short circuit and electrical interference can be reduced.

### BRIEF DESCRIPTION OF THE DRAWINGS

The present invention will be apparent to those skilled in the art by reading the following detailed description of a preferred embodiment thereof, with reference to the attached drawings, in which:

FIG. 1 shows a cross sectional view of a semiconductor load board according to prior arts.

FIG. 2 shows a cross sectional view of a semiconductor load board according to a first embodiment of the present invention.

FIG. 3 shows a cross sectional view of a semiconductor load board according to a second embodiment of the present invention.

FIG. 4 shows a cross sectional view of a semiconductor load board according to a third embodiment of the present invention.

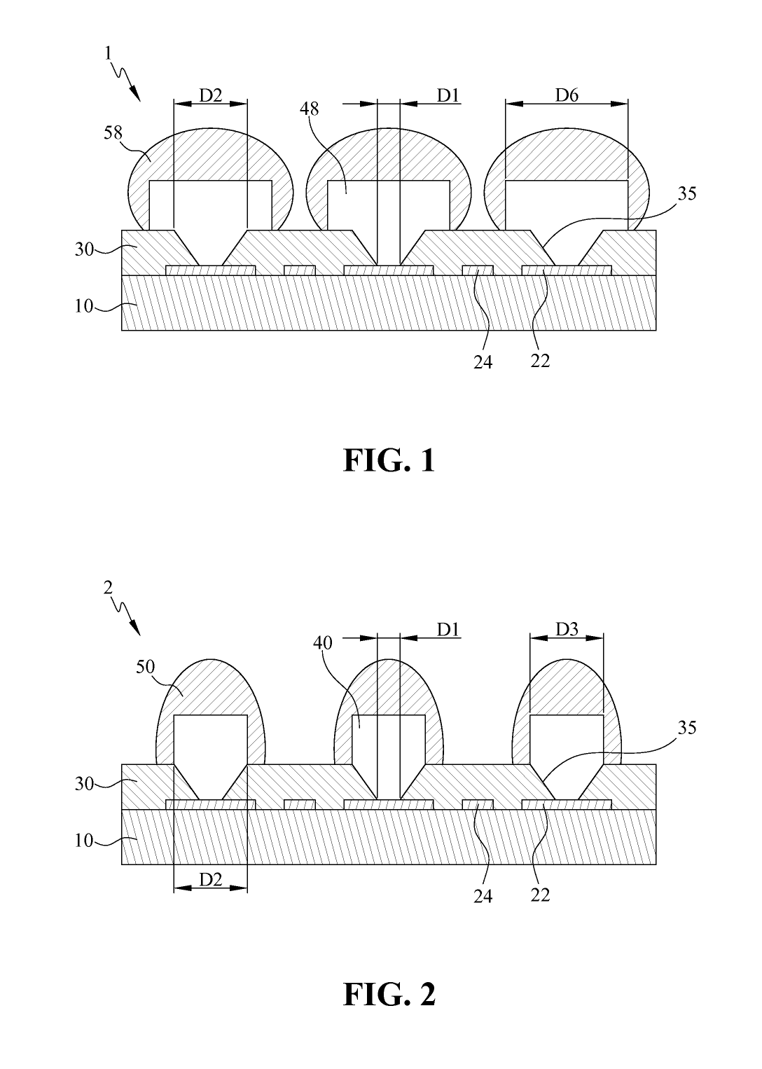

### DETAILED DESCRIPTION OF THE PREFERRED EMBODIMENT

FIG. 2 illustrates the first embodiment of the semiconductor load board of the present invention. As shown in FIG. 2, a semiconductor load board 2 comprises a substrate 10, a plurality of connection pads 22, a patterned circuit layer 24, a dielectric layer 30, a plurality of solder pads 40, and a plurality of solders 50. The substrate 10 is made of polymer materials or ceramic materials, and the polymer materials comprise Bismaleimide Triazine (BT). The connection pads 22 and the patterned circuit layer 24 are located on the substrate 10, and are formed by a first conductive material comprising copper. The dielectric layer 30 is then formed on the substrate, the connection pads 22 and the patterned circuit layer 24, and has a plurality of openings 35 corresponding to the plurality of connection pads 22, wherein the openings 35 have a width reduced gradually toward the connection pads 22, and the minimum width is D1, and the maximum width is D2. The solder pads 40 are formed in the openings 35 corresponding to the connection pads 22 to fill up the openings 35. The solder pads 40 have a height higher than the height of the dielectric layer 30, and the solder pads 40 have a protruding portion which extends above the surface of the dielectric layer, the width D3 of a protruding portion is equals to the maximum width D2 of the openings 35. The solder pads 40 are formed by a second conductive material which is copper or copper with nickel-gold or tin coating. The solders 50 are formed on the each solder pad 40 respectively to cover the solder pad 40 for connecting to external circuits (not shown).

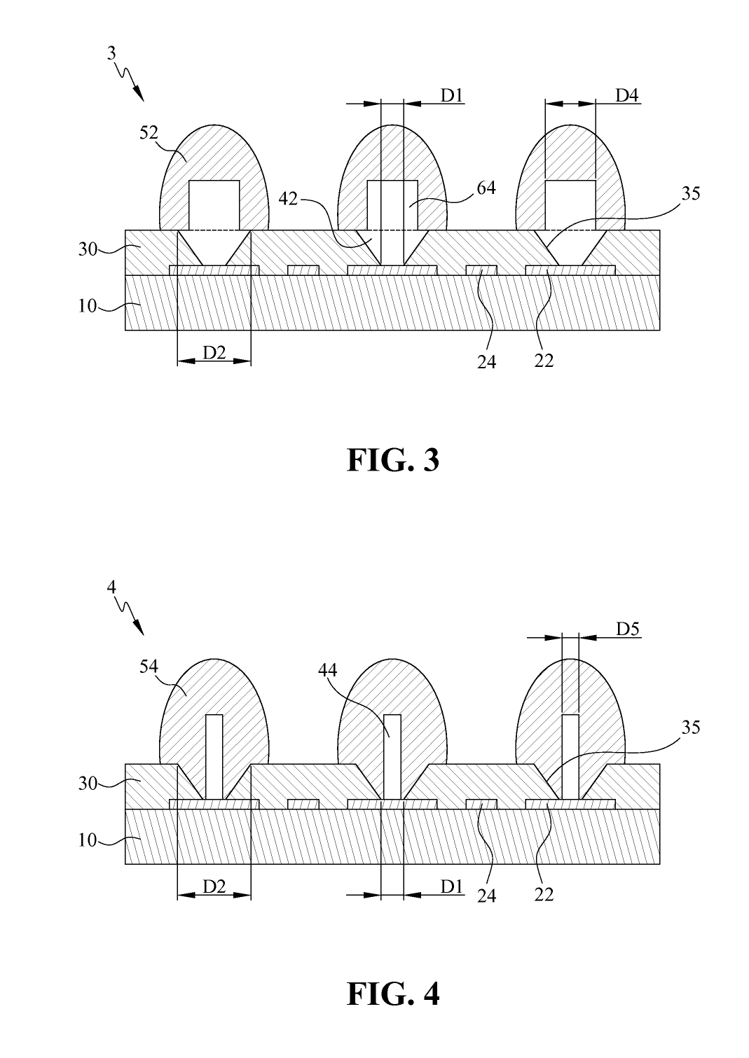

FIG. 3 illustrates the second embodiment of the semiconductor load board of the present invention. As shown in FIG. 3, the second embodiment of the semiconductor load board 3 of the present invention is same as the first embodiment except for the width of the solder pads 42 and solders 52, and same functions and technical characteristics are not described here again. In second embodiment, the solder pads 42 are formed in the openings 35 corresponding to the connection pads 22 to fill the openings 35. The solder pads 42 have a protruding portion 64 which extends above the surface of the dielectric layer 30, and the width D4 of the protruding portion 64 is smaller than the maximum width D2 of the openings 35. The solders 52 are formed on the each solder pad 42 respectively to cover the solder pad 42 for connecting to external circuits (not shown).

FIG. 4 illustrates the third embodiment of the semiconductor load board of the present invention. As shown in FIG. 4, the third embodiment of the semiconductor load board 4 of the present invention is same as the first embodiment except for the width of the solder pads 44 and solders 54, and same functions and technical characteristics are not described here again. In third embodiment, the solder pads 44 are formed in the openings 35, and have a height higher than the height of the dielectric layer 30, and the width D5 of the solder pads 44 is smaller than the minimum width D1 of the openings 35. The solders 54 are formed on the each solder pad 44 respectively to cover the solder pad 44 for connecting to external circuits (not shown), and are partially formed in the openings 35 and connected to the connection pads 22.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A semiconductor load board, comprising:
a substrate made of at least one polymer materials or at least one ceramic materials;
a plurality of connection pads located on the substrate and formed by a first conductive material;
a patterned circuit layer located on the substrate with the connection pads and formed by the first conductive material;
a dielectric layer formed on the substrate, the connection pads and the patterned circuit layer, and has a plurality of openings corresponding to the plurality of connection pads, wherein the openings have a width reduced gradually toward the connection pads;
a plurality of solder pads formed by a second conductive material and formed in the openings corresponding to the connection pads to fill up the openings, each solder pads having a height higher than the height of the dielectric layer, and each solder pads having a protruding portion which extends above a surface of the dielectric layer, a width of the protruding portion being equal to a maximum width of the openings; and
a plurality of solders formed on the each solder pad respectively to cover the solder pad for connecting to external circuits.

2. The semiconductor load board according to claim 1, wherein the at least one polymer material comprises Bismaleimide Triazine (BT).

3. The semiconductor load board according to claim 1, wherein the first conductive material comprises copper.

4. The semiconductor load board according to claim 1, wherein the second conductive material is copper or copper with nickel-gold or tin coating.

5. A semiconductor load board, comprising:
a substrate made of at least one polymer materials or at least one ceramic materials;
a plurality of connection pads located on the substrate and formed by a first conductive material;
a patterned circuit layer located on the substrate with the connection pads, and formed by the first conductive material;
a dielectric layer formed on the substrate, the connection pads and the patterned circuit layer, and has a plurality of openings corresponding to the plurality of connection pads, wherein the openings have a width reduced gradually toward the connection pads;
a plurality of solder pads formed by a second conductive material and formed in the openings corresponding to the connection pads to fill up the openings, each solder pads having a protruding portion which extends above a surface of the dielectric layer, a width of the protruding portion being smaller than a maximum width of the openings; and
a plurality of solders formed on the each solder pad respectively to cover the solder pad for connecting to external circuits.

6. The semiconductor load board according to claim 5, wherein the at least one polymer material comprises Bismaleimide Triazine (BT).

7. The semiconductor load board according to claim 5, wherein the first conductive material comprises copper.

8. The semiconductor load board according to claim 5, wherein the second conductive material is copper or copper with nickel-gold or tin coating.

9. A semiconductor load board, comprising:
a substrate made of at least one polymer materials or at least one ceramic materials;
a plurality of connection pads located on the substrate and formed by a first conductive material;
a patterned circuit layer located on the substrate with the connection pads and formed by the first conductive material;
a dielectric layer formed on the substrate, the connection pads and the patterned circuit layer, and has a plurality of openings corresponding to the plurality of connection pads, wherein the openings have a width reduced gradually toward the connection pads;
a plurality of solder pads formed by a second conductive material and formed in the openings corresponding to the connection pads, each solder pads having a height higher than the height of the dielectric layer, and the width of the solder pads being smaller than a minimum width of the openings; and
a plurality of solders formed on the each solder pad respectively to cover the solder pad for connecting to external circuits, and each solder partially formed in the opening and connected to the connection pads.

10. The semiconductor load board according to claim 9, wherein the at least one polymer material comprises Bismaleimide Triazine (BT).

11. The semiconductor load board according to claim 9, wherein the first conductive material comprises copper.

12. The semiconductor load board according to claim 9, wherein the second conductive material is copper or copper with nickel-gold or tin coating.
